(19) United States
(12) Patent Application Publication
(10) Pub. No.: US 2025/0393462 A1
(43) Pub. Date: Dec. 25, 2025

(54) APPARATUS AND METHOD FOR MANUFACTURING DISPLAY DEVICE

(71) Applicant: Samsung Display Co., Ltd., Yongin-si (KR)

(72) Inventors: Jeong-Seop CHOI, Yongin-si (KR); YONG-WOO KIM, Yongin-si (KR); SEONGSIK CHOI, Yongin-si (KR); DongHun KANG, Yongin-si (KR); JAE-MIN PARK, Yongin-si (KR); Dong Hyeon LEE, Yongin-si (KR); Jeong In LEE, Yongin-si (KR)

(21) Appl. No.: 19/240,558

(22) Filed: Jun. 17, 2025

(30) Foreign Application Priority Data
Jun. 25, 2024 (KR) 10-2024-0083091

(51) Int. Cl. H10K 71/50; B32B 37/10

(52) U.S. Cl. CPC H10K 71/50; B32B 37/10; B32B 2457/20

(57) ABSTRACT

A manufacturing apparatus of a display device includes: a lower chamber configured to support a display panel; an upper chamber opposite the lower chamber and configured to support a cover member; and a driver configured to drive the upper chamber and to control the upper chamber to sequentially move in a first direction, to firstly move by a first distance in a second direction that is opposite to the first direction, and to secondly move by a second distance in the second direction.

### CROSS-REFERENCE TO RELATED APPLICATION

The present application claims priority to and the benefit of Korean Patent Application No. 10-2024-0083091, filed on Jun. 25, 2024, in the Korean Intellectual Property Office, the entire disclosure of which is incorporated herein by reference.

### BACKGROUND

### 1. Field

Aspects of embodiments of the present disclosure relate to an apparatus and method for manufacturing a display device.

### 2. Description of the Related Art

A display device includes a liquid crystal display (LCD), a plasma display device (PDP), an organic light emitting diode device (OLED device), a field emission display (FED), an electrophoretic display, as some examples.

An organic light emitting diode device includes a display panel having a plurality of signal lines and a plurality of pixels and a cover member covering and protecting a display surface of the display panel.

The display panel and the cover member may be joined by an adhesive layer. However, adhesion reliability may deteriorate at an end portion, such as at the corner of the display panel, such that the display panel and the cover member may not be fully joined and may be lifted, and the lifted portion may be visible to the outside.

### SUMMARY

Embodiments of the present disclosure provide a manufacturing apparatus for a display device and a manufacturing method for a display device that may prevent or mitigate adhesion deterioration (e.g., reliability deterioration of adhesion) between the display panel and the cover member.

However, aspects and features of the present disclosure are not limited to the above-described aspects and features.

A manufacturing apparatus of a display device, according to an embodiment, includes a lower chamber configured to support a display panel, an upper chamber opposite the lower chamber and configured to support a cover member, and a driver configured to drive the upper chamber and to control the upper chamber to sequentially move in a first direction, firstly move by a first distance in a second direction that is opposite to the first direction, and secondly move by a second distance in the second direction.

The first distance may be smaller than the second distance.

The driver may be configured to control the upper chamber such that an interval between the lower chamber and the upper chamber becomes smaller when moving in the first direction.

The driver may be configured to control the upper chamber to mount the cover member during the firstly moving.

The driver may be configured to control the upper chamber to detach the cover member from the upper chamber during the secondly moving.

The driver may be configured to control the upper chamber to mount the cover member when moving in the first direction.

The driver may be configured to control the upper chamber to move in a range of 0.1 mm to 0.3 mm during the firstly moving.

The driver may be configured to control the upper chamber to move 0.2 mm during the firstly moving.

The driver may be configured to control the upper chamber to move between 1 second to 3 seconds during the firstly moving.

The driver may be configured to control the upper chamber to move for 2 seconds during the firstly moving.

The driver may be configured to control the cover member to press against the display panel when moving in the first direction.

A manufacturing method of a display device, according to embodiment, includes mounting a display panel in a lower chamber; mounting a cover member to an upper chamber; coating an adhesive layer on the display panel; moving the upper chamber in a first direction so that an interval between the lower chamber and the upper chamber becomes smaller; firstly moving the upper chamber in a second direction by a first distance during a first time; and secondly moving the upper chamber in the second direction by a second distance.

The first distance may be smaller than the second distance.

The firstly moving may be performed in a state in which the cover member is mounted in the upper chamber.

The secondly moving may be performed in a state in which the cover member is detached from the upper chamber.

The first distance may be in a range of 0.1 mm to 0.3 mm and in one embodiment, may be 0.2 mm.

The first time may be in a range of 1 second to 3 seconds and, in one embodiment, may be 2 seconds.

The cover member may press the display panel in a state in which the adhesive layer is between the cover member and the display panel in the moving the upper chamber in the first direction.

According to embodiments of the present disclosure, a manufacturing apparatus for the display device and a manufacturing method for the display device may prevent deterioration of adhesion between the display panel and the cover member.

However, the aspects and features of the present disclosure are not limited to the above-described aspects and features, and it would be apparent to one of ordinary skill in the art that various extensions and various may be made without departing from the spirit and scope of this disclosure.

### BRIEF DESCRIPTION OF THE DRAWINGS

FIG. 1 is a top plan view of a display device according to an embodiment.

FIG. 2 is a cross-sectional view taken along the line I-I′ in FIG. 1.

FIG. 3 is a cross-sectional view of an example of a stacking structure of a display panel in a display device according to an embodiment.

FIG. 4 is a schematic diagram illustrating a manufacturing apparatus for a display device according to an embodiment.

FIG. 5 is a flowchart describing a manufacturing method of a display device according to an embodiment.

FIG. 6 to FIG. 12 are view illustrating steps of a manufacturing method of a display device according to an embodiment.

FIG. 13 is a schematic view of a step of a manufacturing method for a display device according to an embodiment.

FIG. 14 and FIG. 15 are electron microscope photographs showing results of an experimental example.

### DETAILED DESCRIPTION

The present disclosure will be described hereinafter with reference to the accompanying drawings, in which embodiments of the present disclosure are shown. As those skilled in the art would realize, the described embodiments may be modified in various different ways, all without departing from the spirit or scope of this disclosure.

Accordingly, the drawings and description are to be regarded as illustrative in nature and not restrictive.

The accompanying drawings are provided to further describe aspects and features of embodiments disclosed in the present specification so that they may be easily understood and should not be interpreted as limiting the scope of the present disclosure. It is to be understood that this disclosure includes all modifications, equivalents, and substitutions without departing from the scope and spirit of this disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Further, in the specification, the phrase “in a plan view” means when an object portion is viewed from above, and the phrase “in a cross-sectional view” means when a cross-section taken by vertically cutting an object portion is viewed from the side.

Hereinafter, various embodiments of the present disclosure are described in detail with reference to accompanying drawings.

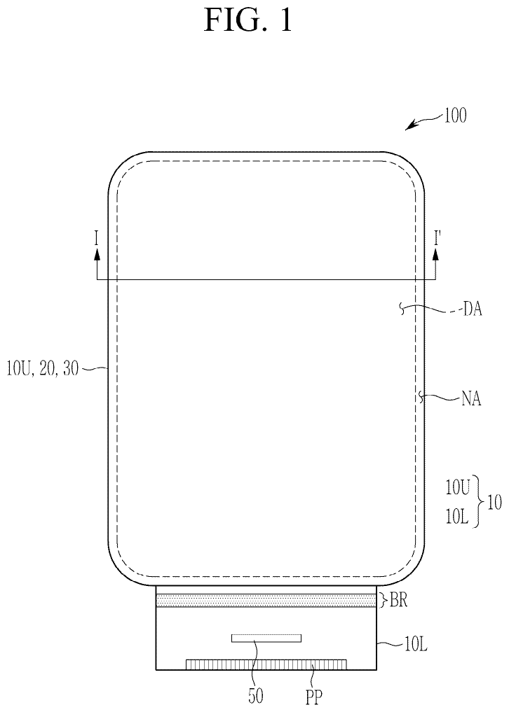

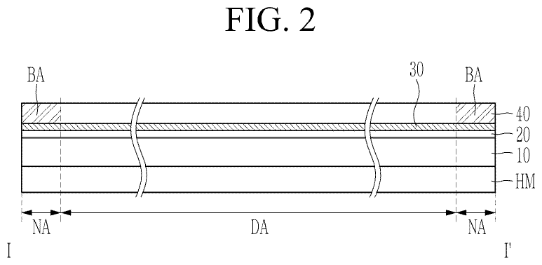

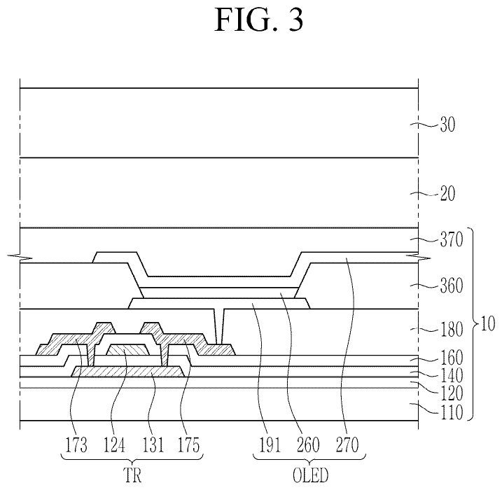

A display device 100, according to an embodiment, is described with reference to FIG. 1 to FIG. 3. FIG. 1 is a top plan view of a display device according to an embodiment. FIG. 2 is a cross-sectional view taken along the line I-I′ in FIG. 1. FIG. 3 is a cross-sectional view showing of a stacking structure of a display panel in a display device according to an embodiment.

Referring to FIG. 1 and FIG. 2, a display device 100, according to an embodiment, may include a display panel 10, a polarization layer 20 and an integrated circuit (IC) chip 50 on the display panel 10, an adhesive layer 30 on the polarization layer 20, and a cover member 40 on the adhesive layer 30.
the display panel 10 includes various components and wirings formed on a flexible substrate made of plastic, etc. The display panel 10 has a display area DA corresponding to a screen that displays (e.g., that is configured to display) the image and a non-display area NA around (e.g., extending around a periphery of) the display area DA. With respect to a boundary line drawn as a dotted line in FIG. 1, the display area DA is inside the boundary line and the non-display area NA is outside the boundary line. Components and/or wirings for generating and/or transmitting various signals applied to the display area DA are in the non-display area NA. In the embodiment illustrated in FIG. 1, the upper large quadrangle portion 10U having the rounded corners corresponds mostly to the display area DA, and the lower small quadrangle portion 10L corresponds to the non-display area NA. The edge portion of the lower small quadrangle portion 10L may correspond to the non-display area NA.

The display area DA of the display panel 10 may be approximately a rectangle, as shown in FIG. 1, and may have rounded corners. The display area DA may have various shapes, such as a rectangle, circle, ellipse, and polygon. The display area DA includes a plurality of pixels. Signal lines, such as gate lines and data lines, are also arranged in the display area DA. Each pixel is connected to the gate line and the data line so that a data signal may be applied from these signal lines at a predetermined timing.

The polarization layer 20 is on the display panel 10. The upper, left, and right edges of the display panel 10 and the upper, left, and right edges of the polarization layer 20 may coincide. The polarization layer 20 may cover the area of the display panel 10 except for the small lower quadrangle area 10L. The polarization layer 20 may cover the entire display area DA and a portion of the non-display area NA. The polarization layer 20 may be attached to or may be over the display panel 10. In the case of an organic light emitting display device, the polarization layer 20 may act as an anti-reflection layer that reduces an external light reflection and increases a contrast ratio and a visibility. The polarization layer 20 may include a linear polarizer and a phase retarder.

The adhesive layer 30 is on the polarization layer 20. The adhesive layer 30 may be formed on the polarization layer 20. The adhesive layer 30 may include an optically clear resin (OCR).

A pad portion PP is in the non-display area NA of the display panel 10, on which pads are arranged to receive signals from outside of the display panel 10 (e.g., from an external device). A flexible printed circuit film may be bonded to the pad portion PP.

A driving apparatus that generates and/or processes various signals for driving the display panel 10 may be in the non-display area NA of the display panel 10. The driving apparatus may include a data driver that applies a data signal to the data line, a gate driver that applies a gate signal to the gate line, and a signal controller that controls the data driver and the gate driver. The data driver and a gate signal controller may be mounted in the non-display area NA in a form of the IC chip 50. The IC chip 50 may be mounted on a flexible printed circuit film and connected to the pad portion PP in a form of a tape carrier package (TCP). The gate driver may be integrated near the left and/or right edges of the display area DA.

The non-display area NA of the display panel 10 may have a bending area BR. In the display panel 10, the bending area BR is bent so that the lower part of the bending area, including the pad portion PP, may be behind (e.g., may be folded behind or under) the display area DA.

The cover member 40 is on display panel 10 and protects the front surface of display panel 10. The cover member 40 may have a transmissive area corresponding to the display area DA and a blocking area corresponding to the non-display area NA. The transmissive area is an optically transparent area and may be an area that transmits incident light. The blocking area may be an area with relatively low light transmittance compared to the transmissive area. The blocking area defines the shape of the transmissive area, and the blocking area may surround (e.g., may extend around a periphery of) the transmissive area. The blocking area may have a color (e.g., a predetermined color). The blocking area overlaps the non-display area NA of the display panel 10, thereby blocking the non-display area NA from being viewed from the outside.

According to an embodiment, the display panel 10 may have a penetrating opening area or a transparent area, and an electron module such as a camera or sensor may be on the back of (e.g., may be arranged or located under) the opening area or the transparent area.

In one embodiment, the display panel 10 may further include a touch sensor configured to detect a user's touch. A touch sensor may be on the front side of the pixel and may include at least one touch electrode.

The housing member HM may be under the lower side of the display panel 10. The housing member HM may be combined with the cover member 40 to form the appearance (e.g., the external appearance) of the display device 100. The housing member HM may include a material having relatively high stiffness. For example, the housing member HM may include a plurality of frames and/or plates composed of glass, plastic, and/or metal. The housing member HM provides (or forms) an accommodation space. The display panel 10 may be accommodated in the accommodation space to be protected from an external impact.

The cover member 40 may have an opaque portion BA corresponding to the non-display area NA.

The cross-section shown in FIG. 3 may generally correspond to one pixel area of the display panel 10. Referring to FIG. 3, the display panel 10 includes a substrate 110, a transistor TR formed on the substrate 110, and an organic light-emitting diode (OLED) connected thereto.

The substrate 110 may be a flexible substrate made of a polymer, such as polyimide, polyamide, or polyethylene terephthalate. In other embodiments, the substrate may be a rigid substrate made of glass or the like. The substrate 110 may include a barrier layer to prevent diffusion of impurities that degrade semiconductor characteristics and to prevent penetration (or entry) of moisture, etc.

A buffer layer 120 is positioned on the substrate 110. The buffer layer 120 may block impurities that may diffuse from the substrate 110 to semiconductor layer 131 during the process of forming the semiconductor layer 131 and may reduce stress received by (or imparted to) the substrate 110.

The semiconductor layer 131 of the transistor TR is on the buffer layer 120, and a gate insulating layer 140 is on the semiconductor layer 131. The semiconductor layer 131 has a source area, a drain area, and a channel area between the source area and the drain area. The semiconductor layer 131 may include polycrystalline silicon, oxide semiconductor, or amorphous silicon. The gate insulating layer 140 may include an inorganic insulating material, such as silicon oxide or silicon nitride.

A gate conductor including the gate electrode 124 of the transistor TR is on the gate insulating layer 140. The gate conductor may include a metal or metal alloy such as, for example, molybdenum (Mo), copper (Cu), aluminum (Al), silver (Ag), chromium (Cr), tantalum (Ta), or titanium (Ti).

An interlayer insulating layer 160 is on the gate conductor. The interlayer insulating layer 160 may include an inorganic insulating material.

A data conductor including the source electrode 173 and the drain electrode 175 of the transistor TR is on the interlayer insulating layer 160. The source electrode 173 and the drain electrode 175 are connected to the source area and the drain electrode of the semiconductor layer 131, respectively, through contact holes (e.g., contact openings) in the interlayer insulating layer 160 and the gate insulating layer 140. The data conductor may include a metal or a metal alloy such as, for example, aluminum (Al), copper (Cu), silver (Ag), molybdenum (Mo), chromium (Cr), gold (Au), platinum (Pt), palladium (Pd), tantalum (Ta), tungsten (W), titanium (Ti), and nickel (Ni).

A passivation layer 180 is on the data conductor. The passivation layer 180 may include an organic insulating material. A pixel electrode 191 is on the passivation layer 180. The pixel electrode 191 may be connected to the drain electrode 175 through a contact hole (e.g., a contact opening) in the passivation layer 180 and may receive a data signal for controlling the luminance of the organic light-emitting diode (OLED).

A pixel definition layer 360 is on the passivation layer 180. The pixel definition layer 360 has an opening corresponding to (e.g., on or over) the pixel electrode 191. A light emitting layer 260 is formed above the pixel electrode 191 in the opening in the pixel definition layer 360, and a common electrode 270 is formed above the light emitting layer 260. The pixel electrode 191, the light emitting layer 260, and the common electrode 270 together form the organic light-emitting diode (OLED). The pixel electrode 191 may be an anode of the organic light-emitting diode (OLED), and the common electrode 270 may be a cathode of the organic light-emitting diode (OLED). The common electrode 270 may include a transparent conductive material, such as indium tin oxide (ITO) or indium zinc oxide (IZO).

An encapsulation layer 370 that protects the organic light-emitting diode (OLED) is on the common electrode 270. The encapsulation layer 370 may include at least one organic material layer and/or at least one inorganic material layer.

A polarization layer 20 for reducing an external light reflection is on the encapsulation layer 370, and an adhesive layer 30 for the attachment to the cover member 40, etc. is on the polarization layer 20. A protective film may be under the substrate 110 to protect the display panel 10.

Although the display device is described as the organic light emitting display device, this is merely an example. In other embodiments, the display device may be a liquid crystal display including, for example, a liquid crystal layer.

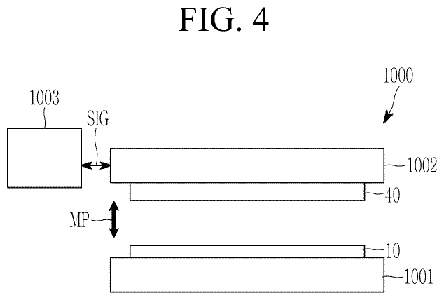

A manufacturing apparatus 1000 for a display device according to an embodiment is described with reference to FIG. 4. FIG. 4 is a simplified diagram illustrating a manufacturing apparatus of a display device according to an embodiment.

Referring to FIG. 4, a manufacturing apparatus 1000 of a display device, according to an embodiment, may include a lower chamber 1001, an upper chamber 1002, and a driver 1003.

The lower chamber 1001 may support (e.g., may accommodate or receive) a display panel 10.

The upper chamber 1002 may support and detach (e.g., may removably attach) the cover member 40. The upper chamber 1002 may operate (MP) by transmitting/receiving a control signal SIG to/from the driver 1003.

The driver 1003 may control the movement of the upper chamber 1002. The driver 1003 controls the gap between the lower chamber 1001 and the upper chamber 1002.

According to the control signal SIG of the driver 1003, the upper chamber 1002 may be operated MP such that the gap between the lower chamber 1001 and the upper chamber 1002 opposing each other changes, and the upper chamber 1002 may support or detach (e.g., may attach or detach) the cover member 40.

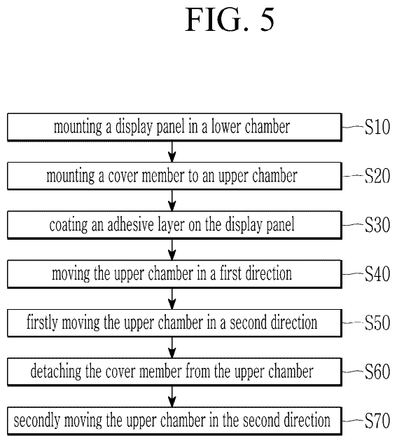

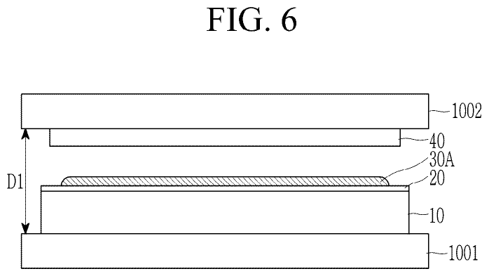

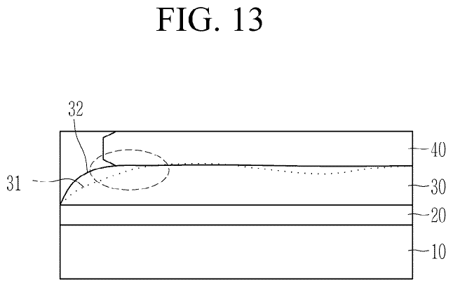

A manufacturing method of the display device according to an embodiment is described with reference to FIG. 6 to FIG. 13 along with FIG. 5. FIG. 5 is a flowchart describing a manufacturing method of a display device according to an embodiment. FIG. 6 to FIG. 12 are view illustrating steps of a manufacturing method of a display device according to an embodiment. FIG. 13 is a schematic view of a manufacturing method for a display device according to an embodiment.

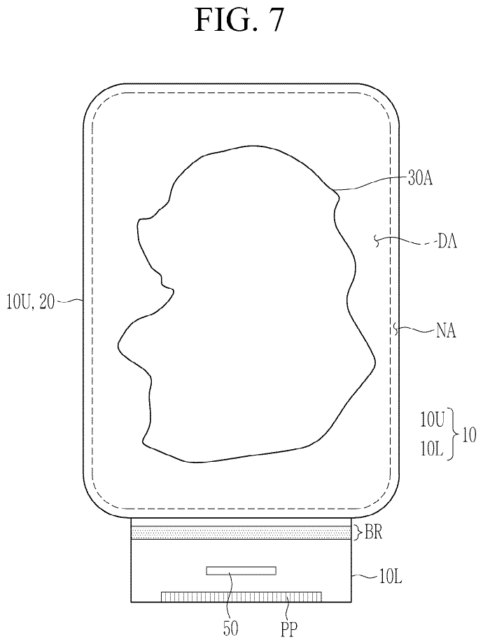

Referring to FIG. 6 and FIG. 7 along with FIG. 5, the display panel 10, to which the polarization layer 20 is attached, may be mounted to the lower chamber 1001 of the manufacturing apparatus 1000 of the display device (S10), the cover member 40 may be mounted to the upper chamber 1002 (S20), and an adhesive material layer 30A may be coated on the display panel 10 mounted onto the lower chamber 1001 (S30).

The lower chamber 1001 and the upper chamber 1002 may be spaced apart facing each other to form a first interval D1.

The adhesive material layer 30A may be applied in a form of a liquid or paste within the display area DA of the display panel 10.

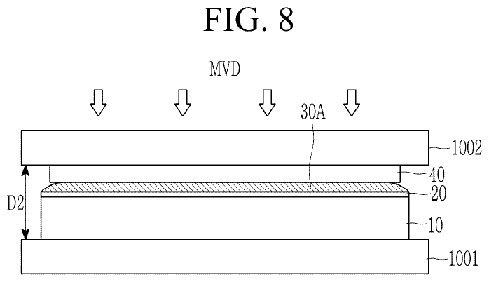

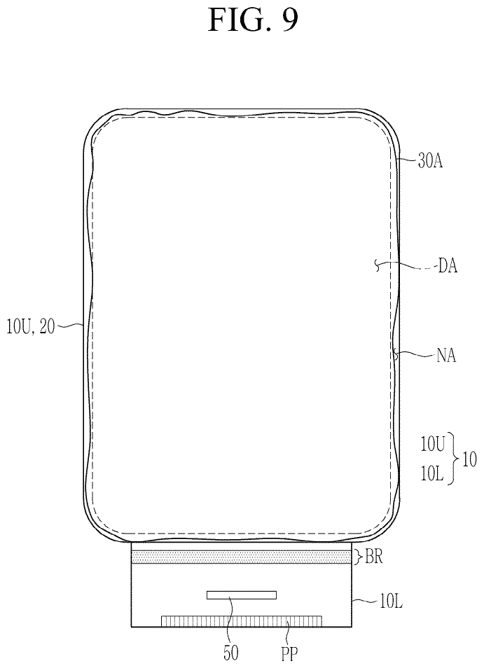

Referring to FIG. 8 and FIG. 9 along with FIG. 5, according to the control signal SIG of the driver 1003, the upper chamber 1002 may move S40 in a first direction MVD. The first direction MVD may be a direction in which the interval between the lower chamber 1001 and the upper chamber 1002 becomes closer (or smaller), for example, in the step (S40), the upper chamber 1002 may descend.

As the upper chamber 1002 moves in the first direction MVD (S40), a second interval D2 between the lower chamber 1001 and the upper chamber 1002 may be narrower than the first interval D1 such that the cover member 40 mounted on the upper chamber 1002 may contact the adhesive material layer 30A and compress the adhesive material layer 30A. Accordingly, the adhesive material layer 30A may be diffused to the entire display area DA of the display panel 10 and a part of the non-display area NA.

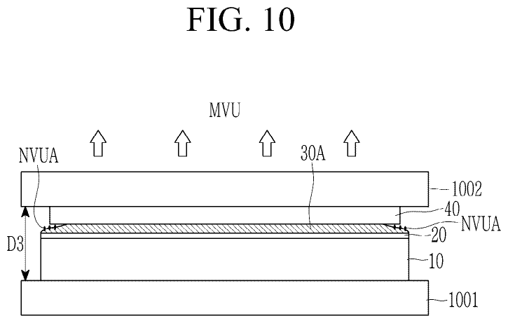

Along with FIG. 5, referring to FIG. 10, according to the control signal SIG of the driver 1003, the upper chamber 1002 may firstly move in a second direction MVU, which is the opposite direction to the first direction MVD (S50).

At this time, the movement distance of the upper chamber 1002 in the firstly moving (S50) may be smaller than the movement distance in the moving (S40).

For example, the movement distance of the upper chamber 1002 at the firstly moving (S50) may be in a range of about 0.1 mm to about 0.4 mm, in some embodiments, in a range of about 0.1 mm to about 0.3 mm, and in one embodiment, about 0.2 mm.

Through the firstly moving (S50), the third interval D3 between the lower chamber 1001 and the upper chamber 1002 may be widened (or increased) by the movement distance of the upper chamber 1002 more than (or with respect to) the second interval D2.

By slightly moving the upper chamber 1002 in the second direction MVU at the firstly moving (S50), due to the viscosity of the adhesive material layer 30A in the form of liquid or paste, the adhesive material layer 30A, which is partially positioned at the edge of the non-display area NA of the display panel 10, may move along the movement direction NVUA of the cover member 40.

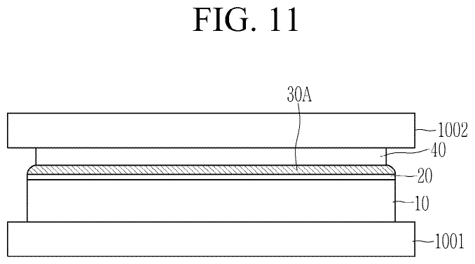

Through this, as shown in FIG. 11, the adhesive material layer 30A may be diffused to the edge of the cover member 40.

The firstly moving (S50) may take in a range of about 1 second to about 3 seconds and, in one embodiment, may take about 2 seconds. If the movement distance of the upper chamber 1002 is too large or the movement time is too long at the firstly moving (S50), the adhesive material layer 30A, which moves together along the movement direction NVUA of the cover member 40, may return to an original position thereof.

The driver 1003 of the manufacturing apparatus 1000 of the display device may control the movement distance and the movement time of the upper chamber 1002 in the firstly moving (S50) so that the adhesive material layer 30A may be maintained in the diffusion state up to the edge of the cover member 40.

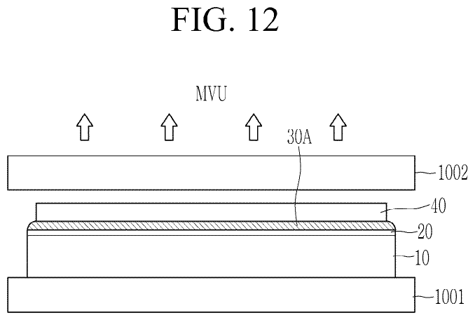

Referring to FIG. 12 along with FIG. 5, according to the control signal SIG of the driver 1003, the cover member 40 may be detached from the upper chamber 1002 S60, and the upper chamber 1002 from which the cover member 40 is detached may secondly move in the second direction MVU for the second time (S70), and through the secondly moving (S70), the upper chamber 1002 may be separated from the lower chamber 1001 to form the first interval D1.

Next, the adhesive material layer 30A that has been diffused to the edge of the cover member 40 may be cured to form the adhesive layer 30.

According to the manufacturing apparatus and the manufacturing method of the display device according to an embodiment, according to (or depending on) the control signal SIG of the driver 1003, as the upper chamber 1002 descends, the cover member 40 mounted on the upper chamber 1002 may contact the adhesive material layer 30A and may compress the adhesive material layer 30A, and as the upper chamber 1002 firstly moves upwardly, the adhesive material layer 30A, which is partially positioned at the edge of the non-display area NA of the display panel 10, moves together along the movement direction NVUA of the cover member 40, the adhesive material layer 30A may be diffused to the edge of the cover member 40, and after the cover member 40 is detached from the upper chamber 1002, the upper chamber 1002 secondly moves upwardly, and then the adhesive material layer 30A may be cured.

Referring to FIG. 13, when the adhesive material layer 31 does not diffuse to the edge of the cover member 40 after descending the upper chamber 1002, the adhesive material layer 31 may have an inclined end at the edge of the cover member 40 and an air gap, etc. may be formed in this area. However, by firstly moving (S50) of the upper chamber 1002, the adhesive material layer may move along the movement direction of the cover member 40, so that the adhesive material layer 32 may be uniformly positioned to the end of the cover member 40.

As above described, by firstly moving (S50) the upper chamber 1002, as the adhesive material layer 30A moves NVUA together with the movement direction of the cover member 40, the adhesive material layer 30A may be diffused to the edge of the cover member 40, and thus, the adhesive layer 30 may be uniformly formed at the edge of the cover member 40.

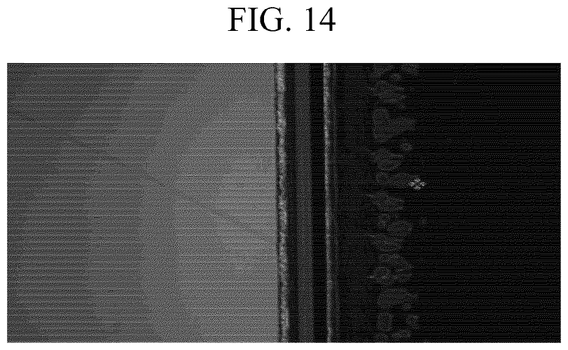

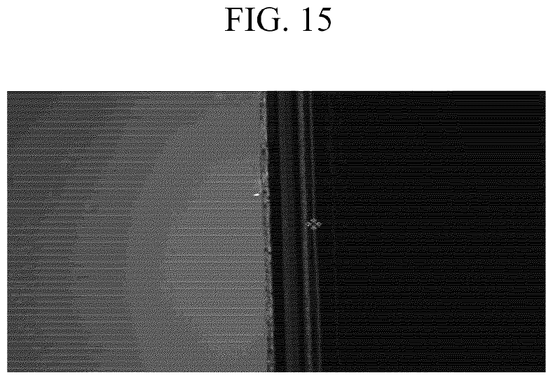

An experimental example is described with reference to FIG. 14 and FIG. 15. FIG. 14 and FIG. 15 are electron microscope photographs showing results of an experimental example. In the present experimental example, first case omits the firstly moving (S50) and a second case includes the firstly moving (S50) such as the manufacturing apparatus and the manufacturing method of the display device according to the embodiment. In both cases, the upper surface of the display device on the cover member was attached was measured using an electron microscope, and the results are shown in FIG. 14 and FIG. 15. Except for omitting or performing the firstly moving (S50), all other conditions in the first and the second cases were the same.

FIG. 14 shows the result of the first case, and FIG. 15 shows the result of the second case.

Referring to FIG. 14, in the experimental example according to the first case in which the firstly moving was omitted, the adhesive layer was not filled at the edge of cover member 40, resulting in an air gap, and this air gap is visible. In the area where the air gap occurs, it may be seen that the adhesive strength of display panel 10 and the cover member 40 is reduced or deteriorated.

On the other hand, according to the second case including the firstly moving (S50), such as the manufacturing apparatus and manufacturing method of the display device according to the embodiment described above, as shown in FIG. 15, the adhesive layer was well filled up to the edge of cover member 40, and the adhesive layer 30 was uniformly formed on the edge of the cover member 40.

While this disclosure has been described in connection with what is presently considered to be practical embodiments, it is to be understood that the present disclosure is not limited to the disclosed embodiments, but, on the contrary, is intended to cover various modifications and equivalent arrangements included within the spirit and scope of the appended claims and their equivalents.

### DESCRIPTION OF SOME REFERENCE SYMBOLS

1000: manufacturing apparatus of display device
1001: lower chamber
1002: upper chamber
1003: driver
100: display device
10: display panel
20: polarization layer
30: adhesive layer
30A: adhesive material layer
40: cover member
HM: housing member

What is claimed is:

1. A manufacturing apparatus of a display device comprising:
a lower chamber configured to support a display panel;
an upper chamber opposite the lower chamber and configured to support a cover member; and
a driver configured to drive the upper chamber and to control the upper chamber to sequentially move in a first direction, to firstly move by a first distance in a second direction that is opposite to the first direction, and to secondly move by a second distance in the second direction.

2. The manufacturing apparatus of the display device of claim 1, wherein the first distance is smaller than the second distance.

3. The manufacturing apparatus of the display device of claim 2, wherein the first direction is a direction from the upper chamber toward the lower chamber.

4. The manufacturing apparatus of the display device of claim 2, wherein the driver is configured to control the upper chamber to secure the cover member during the firstly moving.

5. The manufacturing apparatus of the display device of claim 4, wherein the driver is configured to control the upper chamber to detach the cover member during the secondly moving.

6. The manufacturing apparatus of the display device of claim 5, wherein the driver is configured to control the upper chamber to secure the cover member when moving in the first direction.

7. The manufacturing apparatus of the display device of claim 2, wherein the driver is configured to control the upper chamber to move in a range of 0.1 mm to 0.3 mm during the firstly moving.

8. The manufacturing apparatus of the display device of claim 7, wherein the driver is configured to control the upper chamber to move 0.2 mm during the firstly moving.

9. The manufacturing apparatus of the display device of claim 7, wherein the driver is configured to control the upper chamber to move for between 1 second and 3 seconds during the firstly moving.

10. The manufacturing apparatus of the display device of claim 7, wherein the driver is configured to control the upper chamber to move for 2 seconds during the firstly moving.

11. The manufacturing apparatus of the display device of claim 2, wherein the driver is configured to control the cover member to press against the display panel when moving in the first direction.

12. A manufacturing method of a display device, the method comprising:
mounting a display panel in a lower chamber;
mounting a cover member to an upper chamber;
coating an adhesive layer on the display panel;
moving the upper chamber in a first direction so that an interval between the lower chamber and the upper chamber becomes smaller;
firstly moving the upper chamber in a second direction by a first distance for a first time; and
secondly moving the upper chamber in the second direction by a second distance.

13. The manufacturing method of the display device of claim 12, wherein the first distance is smaller than the second distance.

14. The manufacturing method of the display device of claim 13, wherein the firstly moving is performed in a state in which the cover member is mounted in the upper chamber.

15. The manufacturing method of the display device of claim 13, wherein the secondly moving is performed in a state in which the cover member is detached from the upper chamber.

16. The manufacturing method of the display device of claim 13, wherein the first distance is in a range of 0.1 mm to 0.3 mm.

17. The manufacturing method of the display device of claim 16, wherein the first distance is 0.2 mm.

18. The manufacturing method of the display device of claim 16, wherein the first time is in a range of 1 second to 3 seconds.

19. The manufacturing method of the display device of claim 18, wherein the first time is 2 seconds.

20. The manufacturing method of the display device of claim 12, wherein the cover member presses the display panel in a state in which the adhesive layer is between the cover member and the display panel in the moving the upper chamber in the first direction.
